(19) United States
(12) Patent Application Publication
(10) Pub. No.: US 2005/0139780 A1
(43) Pub. Date: Jun. 30, 2005

(54) Apparatus and method for implantation of elements, species and compositions in nanostructured materials

(76) Inventor: Timothy James Imholt, Carrollton, TX (US)

Correspondence Address: Jackson Walker L.L.P., Suite 600, 2435 North Central Expressway, Richardson, TX, 75080, US

(21) Appl. No.: 11/014,477

(22) Filed: Dec. 16, 2004

Related U.S. Application Data
(60) Provisional application No. 60/530,433, filed on Dec. 17, 2003.

(51) Int. Cl. C01B 31/00; C23C 14/00

(52) U.S. Cl. 250/423 R; 427/523; 423/445 B

(57) ABSTRACT

A practical method and apparatus for implanting elements, such as hydrogen, argon and krypton, and other compositions in a nanotube structure is disclosed. More specifically, such invention comprises, in one embodiment, an ion beam line apparatus used in conjunction with the requisite ancillary equipment necessary to accurately control the energy of an accelerated beam of hydrogen toward a nanostructured material.

### CROSS REFERENCE TO RELATED APPLICATION

This application is related to U.S. provisional patent application No. 60/530,433, filed Dec. 17, 2003, entitled “GAS IMPLANTATION OF NANOSTRUCTURED MATERIALS”, the entire contents of which are incorporated herein by this reference. The Applicants hereby claim the benefits of this provisional application under 35 U.S.C. Section 119(e).

### FIELD OF THE INVENTION

The present invention relates to methods and apparatus for implanting and storing chemical elements, such as but not limited to hydrogen, argon and krypton, species and compositions, in nanostructured materials, such as carbon or silica nanotubes.

### BACKGROUND OF THE INVENTION

Fossil fuels are used as an energy source in a wide variety of applications, including as a method of powering automobile engines, and power plants which convert chemical energy into electrical energy. It is well known that fossil fuels are finite in supply and pose hazards due to release of various environmental toxins as byproducts of their combustion. Hydrogen has been proposed as a possible replacement fuel for many applications in which fossil fuel is used as the energy source. In order for hydrogen to replace fossil fuel there are a number of obstacles that must be overcome. These include, among other things, the economical production of hydrogen; efficient and practical distribution methods of hydrogen; and safe, cost-effective and efficient storage methods. In addition there would be benefits of having a safe, cost-effective and efficient storage method for other gaseous elements, including krypton and argon.

A variety of different storage systems for elements such as hydrogen have been proposed and are currently under development. These systems include physical storage by compression of liquefied gas, chemical storage in non-reversible, hydrogen carriers; reversible metal and chemical hydride batteries, and gas adsorbed onto solids. Regardless of the storage medium employed, it is generally understood that two objectives must be met in order for these systems to be viable for large scale commercialization in the hydrogen context. The first is that some percentage of the weight of the storage matrix must be hydrogen, for example, 6.5 percent, and that at least some amount of hydrogen must fit into a cubic meter, for example, 62 kilograms per cubic meter.

Although several automobile manufacturers have produced prototypes of fuel cell vehicles as proof-of-concept cars, a major limiting factor in the commercialization of these vehicles is the means of storing liquid hydrogen under pressure. Liquid hydrogen evaporates at a rate of approximately one percent per day, and as much as 30 percent of the hydrogen evaporates at the time of re-fueling. In addition, a significant number of layers of insulation is required to keep the hydrogen cooled to 20 Kelvin. This is the temperature of liquid hydrogen temperature at atmospheric pressure. As the pressure increases, the temperature at which hydrogen remains a liquid rises. Automobiles using these high pressure storage systems, require a large amount of energy input in order to achieve pressurization of the fuel at the time of re-fueling. There are also significant safety issues associated with the high pressure storage of hydrogen, primarily explosions in the event of a rupture of a high pressure cell.

Metal hydride storage cells and associated systems have been explored as an alternative to storing liquid hydrogen under pressure. However, these systems also have several disadvantages. For example, these systems require a large amount of energy to desorb the hydrogen from the system, which reduces the overall efficiency of the engine. Hydride systems are used in a type of hybrid engine that employs a small fuel cell to power the automobiles engine at times of low energy consumption and a internal combustion engine during times of high power requirements. These systems are complex and not cost effective. What is desired is a method and apparatus for safely and cost-effectively implanting and storing a fuel, such as hydrogen, in a material matrix, such as nanotubes. Such a storage mechanism would also have advantages for storing other elements such as krypton and argon, as well as other compositions.

### SUMMARY OF THE INVENTION

The present invention is directed toward apparatus and methods of implanting and storing elements, such as but not limited to hydrogen gas, in a nanostructured material or matrix such as carbon and/or silica nanotubes. These foregoing represent only two such nanostructured materials and the same process will work with all nanotube type structures. Other elements, species and compositions can be stored in a nanostructured matrix using the apparatus of the present invention, including argon and krypton. In one embodiment of the present invention, an apparatus and method of implanting and storing hydrogen gas in nanostructured materials, specifically carbon nanotubes, is disclosed. Carbon nanotubes offer a significant external surface area for storage based their size, and also have an inner volume capable of storing a substantial amount of hydrogen safely. Most conventional storage techniques involve physical adsorption to the surfaces of various materials to serve as a matrix for long term storage of gases for use in such things as fuel cells. Most experimental evidence reveals that, even with nanotubes that have been placed in a high pressure hydrogen environment, their storage capacities are correspondent with the predicted level of external storage seen in the adsorption process. In order to improve this storage capacity of nanotubes (not necessarily made from carbon but any nanotube structure), a method and apparatus of forcing the hydrogen in to the inner volume of the structure is necessary.

It has been proposed, and shown in many theoretical studies that internal storage of hydrogen in nanotubes, particularly in carbon nanotubes, will offer a safe and efficient method of storage. Such a storage mechanism would also have advantages for storing other elements such as krypton and argon, as well as other compositions. However, prior to the present invention, a method of, and apparatus for, implanting elements, such as hydrogen gas, into the inner pore region of nanostructures has not been discovered, or demonstrated experimentally. The apparatus and method of the present invention disclose a method of, and apparatus for, implanting these elements, such as hydrogen gas, into the inner pore region of a nanostructured material, such as a carbon and/or silica nanotube.

### DESCRIPTION OF THE DRAWINGS

The features of the present invention will be more clearly understood from consideration of the following description in connection with accompanying drawings in which:

FIG. 1 shows the results of desorption experiments from samples implanted with hydrogen and samples not implanted with hydrogen;

FIG. 2 is a plot showing the optical emission of non-implanted buckypearls; and

FIG. 3 is a plot showing the optical emission of implanted buckypearls.

### DETAILED DESCRIPTION OF ILLUSTRATIVE EMBODIMENTS

A method and apparatus of implanting elements, such as hydrogen gas, in to the inner volume of a nanostructured material or matrix is disclosed. The present invention comprises a method and apparatus for improving the storage capacity of such nanostructured materials or matrices. In an embodiment of the present invention, an ion beam gun is used to impart energy to particles that are directed toward the nanostructured material or matrix. In such embodiment., the nanostructured material or matrix comprises a single or multi walled carbon nanotube or silica nanotube. The apparatus of the present invention thus is adapted to cause particles to channel into the inner pore of such a nanotube. In order for the hydrogen to enter the inner volume of the nanotubes, it is necessary for the hydrogen to force a void in the nanotube wall whereby the hydrogen can enter the nanotube. According to theoretical models, this can be achieved by forcing the hydrogen to impact the nanotube surface with somewhere between approximately 2 eV to 20 eV of energy depending on the tube configuration and diameter. While it would seem problematic to open a hole in the nanotube, as such holes would seem to allow gas to escape the nanostructure, such is not the case. Nanotubes are well-known to self repair this type of damage in approximately 1 pico-second. This self repair is rapid enough that almost no hydrogen escapes prior to the damaged nanotube self-repairing. A spread of energies at which the hydrogen is impacted into the nanotube allows for implantation at the surface of the nanotube sample and at varying depths into the sample, allowing for more efficient storage performance.

The present invention comprises a practical method and apparatus for implanting elements, such as hydrogen, argon and krypton, and other compositions in a nanotube structure. More specifically, such invention comprises, in one embodiment, an ion beam line apparatus used in conjunction with the requisite ancillary equipment necessary to accurately control the energy of an accelerated beam of hydrogen.

The experimental run of the present invention comprised a 4 mg sample of carbon nanotubes being placed in the ion beam line with the incident energy of hydrogen impacting the carbon nanotubes at approximately 50 keV. In the preliminary experiments, the distance from the ion beam gun to the carbon nanotube sample was approximately 50 feet. However, due to the nature of the interaction and the sizes of the particles, any distance below 500 feet is negligible in the difference of the outcome of the implantation process. The kinetic energy of the hydrogen particles are reduced, once they impact and as they pass through the successive nanotubes. Once the speed of the hydrogen particles decrease to a certain level, it is captured in the nanotube. Generally, the decreased level to implant in a single nanotube is between 10 eV and 30 eV. The distance through the nanotube that a hydrogen particle travels is dependent on the energy level of the hydrogen particle entering the matrix. The thickness of nanotube 1.0 nm penetrated can generally be determined by dividing the thickness of the nanotube 1,000,000 nm by approximately 20 eV. The result of this calculation will correspond generally to how deep the particles will penetrate. Using the energy levels disclosed herein, a hydrogen particle with an a kinetic energy of about 60 eV will penetrate approximately 15 nanotubes. In this manner, implantation can be achieved using higher energy levels than was previously thought possible. A particle impact rate of approximately 1 particle every 10⁻⁹ seconds was used in the method and apparatus which is slow enough to allow self-repairing of the nanotubes. The self repair process which nanotubes undergo is the fundamental phenomena that allows this to be a safe process. Without this self repairing characteristic, hydrogen could leak from the sample, increasing the chance for random ignition.

The carbon sample was placed in the apparatus in such a way as to measure not only the total charge incident on the sample but also charge channeling and escape. In this manner, the total number of trapped particles can be determined. This was calculated to be approximately 10¹⁷ hydrogen atoms out of approximately 10¹⁷ hydrogen atoms directed at the nanotube matrix.

Once the carbon nanotube samples were prepared, desorption of two almost identical nanotube samples was conducted. Sample A consisted of 4 mg of single walled nanotubes (“SWNTs”) which had not been implanted with hydrogen via the ion beam line implantation method described above, but were bathed in an environment of approximately 100 torr of hydrogen for 1 hour. Sample B was also bathed in an environment of approximately 100 torr of hydrogen for 1 hour and then implanted with approximately 10¹⁷ hydrogen atoms using the method and apparatus described above.

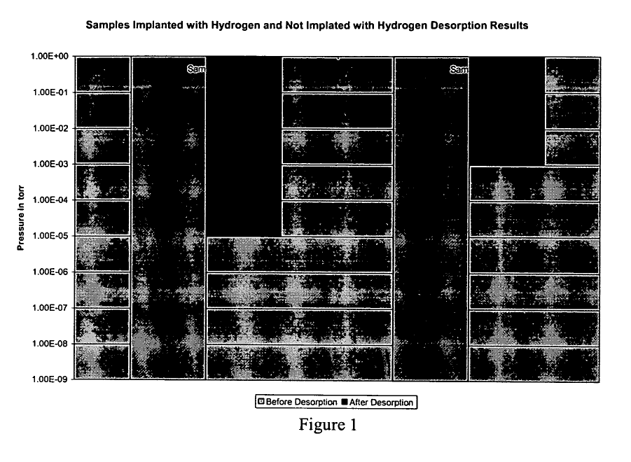

As seen in FIG. 1, the results of the subsequent desorption experiment showed a large increase in the amount of stored hydrogen. For Sample A, it was found that the levels of hydrogen in the vacuum system rose from approximately 10⁻⁹ torr to approximately 10⁻⁵ torr. For Sample B, using the same vacuum system, residual gas analyzer (“RGA”) analysis showed a level of approximately 10⁻⁹ torr of hydrogen previous to desorption and complete saturation of the instrumentation on the hydrogen channel following desorption. As the RGA does not saturate until 10⁻³ torr, these results indicate that a large increase in the amount of stored hydrogen was removed from the sample.

Using the method and apparatus disclosed, it is possible to implant hydrogen particles in areas inside the nanotubes using ion beam techniques. This method, and the related apparatus, forces the hydrogen into the inner volume of the structure. In order for the hydrogen to enter the nanotube, it is necessary for the hydrogen to force open a void or hole in the side of the nanotube for the hydrogen to enter the inner volume. This occurs when the hydrogen particle impacts the surface of the nanotube with between approximately 2 keV and 50 keV of incident energy. Conventional storage matrixes having large voids in the walls thereof tend not to store gaseous elements therein for prolonged durations. Such is not the case with multi and single walled carbon nanotubes as these materials are known to self repair the damage in approximately 1 picosecond. The self-repair characteristic is rapid enough such that almost no stored gaseous elements are able to escape from the storage vessel. The method and apparatus of the present invention permits an increase in the ability of a nanotube to store hydrogen at an amount from less than 10 percent hydrogen to the weight of the storage material and fuel to more than 20 percent hydrogen to the weight of the storage material and fuel and potentially as high as 50 percent hydrogen to the weight of the storage material and fuel, or greater.

The apparatus used to implement the present invention comprises a device to accelerate the element to be stored, such as hydrogen, toward the nanostructure, such device being, for example, a small ion gun, which can be located inside a vacuum system. The acceleration can also be achieved in a pure, such as hydrogen, environment. The ion gun would be operable to direct the particles, such as hydrogen gas, at the nanotube storage matrix. If energy in excess of 50 keV is used to accelerate the particles, the nanotube storage matrix can be refueled en masse since hydrogen will channel from one tube to the next until it decelerates enough to be captured either internally or externally by some nanotubes below the surface of the nanotube matrix.

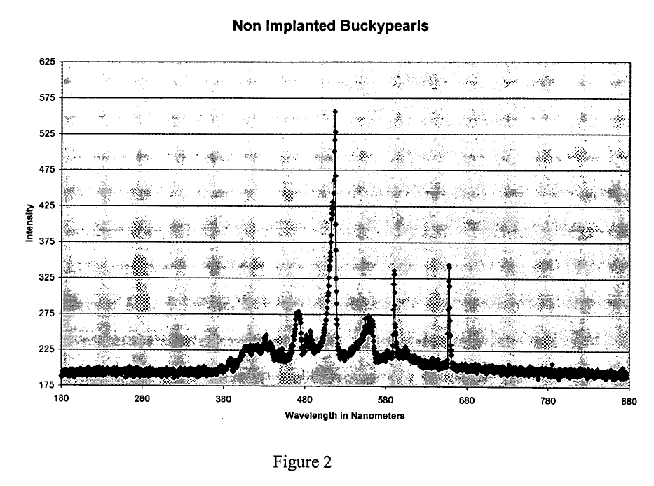

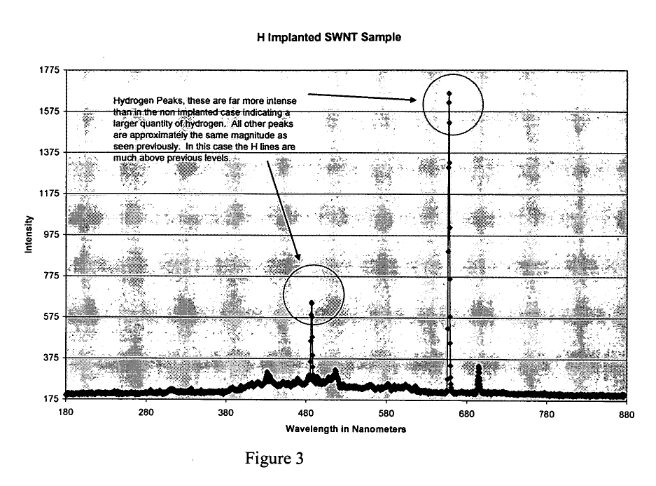

FIG. 2 is a complex light emission plot illustrating the result of a conventional means of storing hydrogen. For comparison, FIG. 3 is a complex light emission plot illustrating the result of the use of the method and apparatus of the present invention. The peaks of interest 301 for this particular experiment are the hydrogen peaks which are labeled in FIG. 3. These peaks can also be seen in FIG. 2, but are less obvious as the levels of hydrogen in those particular samples are very low. As can be seen by comparing the plot of FIG. 2 to the plot of FIG. 3, the increase caused by the implantation process has caused a ten to twelve fold increase in the level of hydrogen present in these samples. This indicates a larger quantity of hydrogen in the nanostructured material.

Other methods and apparatus whereby hydrogen storage in nanotubes have been attempted have failed to produce viable evidence of increased capacity for long term storage. The method and apparatus of the present invention provides a safe, non-complex method of implantation of elements, such as hydrogen, argon or krypton, in a nanostructured material such as carbon and/or silica nanotube.

The method and apparatus disclosed herein could further advance the understanding the energy levels required to implant nanotubes with various elements on the periodic table. For example, the method and apparatus of the present invention could be extended to improve plasma deposition techniques. Further, the present invention could allow long term storage and retrieval of any number of types of gasses. This present invention would allow new methods of implantation in materials additive manufacturing (“MAM”).

While this invention has been described with reference to illustrative embodiments, this description is not intended to be construed in a limiting sense. Various other methods, modifications and combinations of the illustrative embodiments, as well as uses of other elements or compositions as the material to be implanted, as well as other embodiments of the invention, will be apparent to persons skilled in the art upon reference to the description. It is therefore intended that the appended claims encompass any such modifications or embodiments.

1. An apparatus for implanting and storing fuel, comprising:
a nanostructured material;
a device for imparting energy to a chemical element, species or composition; and
said energy imparting device being adapted to direct an ejected chemical element, species or composition toward the nanostructured material.

2. The apparatus of claim 1, wherein the nanostructured material comprises one from the group consisting of single walled carbon nanotubes, multi-walled carbon nanotubes and silica nanotubes.

3. The apparatus of claim 1, in combination with a chemical element, species or composition.

4. The apparatus of claim 3, wherein the chemical element comprises one from the group consisting of hydrogen, argon and krypton.

5. The apparatus of claim 1, wherein the device for imparting energy to a chemical element, species or composition further comprises an ion beam gun.

6. The apparatus of claim 5, wherein the device for imparting energy to a chemical element, species or composition is adapted to impart between 2 eV and 100 keV to the chemical element, species or composition.

7. The apparatus of claim 6, wherein the device for imparting energy to a chemical element, species or composition varies the energy imparted to the chemical elements, species or compositions to more efficiently fill the nanostructured material.

8. The apparatus of claim 1, wherein the nanostructured material and device for imparting energy to a chemical element, species or composition are located inside a vacuum apparatus.

9. The apparatus of claim 8, wherein the vacuum apparatus is adapted to provide a vacuum pressure of between 10⁻⁴ and 10⁻⁹ torr.

10. The apparatus of claim 1, wherein the distance between the device for imparting energy to a chemical element, species or composition and the nanostrucutred material is between 1 meter and 153 meters.

11. The apparatus of claim 1 further comprising:
the nanostructured material comprising carbon nanotubes; and
the device for imparting energy to a chemical element, species or composition comprising an ion beam gun adapted to impart varying amounts of energy to particles of chemical elements, species or compositions to be ejected therefrom.

12. The apparatus of claim 11 further comprising the chemical element being from the group consisting of hydrogen, argon and krypton particles.

13. The apparatus of claim 11, wherein the ion beam gun is adapted to impart varying amounts of energy to the particles such that the particles impact the carbon nanotubes with a kinetic energy level of between about 25 keV and 75 keV.

14. The apparatus of claim 11, wherein the ion beam gun is adapted to impart varying amounts of energy to the particles such that the particles impact the carbon nanotubes with a kinetic energy level of between about 30 keV and 60 keV.

15. The apparatus of claim 11, wherein the distance between the end of the ion beam gun to the carbon nanotubes is between 3 meters and 23 meters.

16. The apparatus of claim 11, wherein the distance between the end of the ion beam gun to the carbon nanotubes is between 8 meters and 18 meters.

17. The apparatus of claim 1, for use in materials additive manufacturing (“MAM”).

18. The apparatus of claim 1, adapted for use in a vehicle.

19. An apparatus for implanting and storing hydrogen, comprising:
a carbon nanotube matrix; and
a device adapted to generate varying energy levels for accelerating hydrogen particles with varying amounts of kinetic energy toward the carbon nanotube matrix.

20. The apparatus of claim 19 wherein the device comprises an ion beam gun located inside a vacuum system.

21. A method of implanting particles of a chemical element, species or composition in a nanostructured material, comprising:
directing particles of a chemical element, species or composition at a nanotube matrix at constant or varying levels of energy;
causing the particles to impact the nanotube matrix; and
capturing, either internally or externally, the particles on and below the surface of the nanotube matrix.

22. The method of claim 21, wherein the particles have an energy level when they impact the nanotube matrix of approximately 50 keV.

23. The method of claim 21, wherein the particles comprise one from the group consisting of hydrogen, argon and krypton.

24. The method of claim 21, wherein the nanotube matrix comprises one from the group consisting of a carbon nanotube matrix and a silica nanotube matrix.

25. A method of storing hydrogen in a carbon nanotube storage matrix, comprising:
directing hydrogen particles at a carbon nanotube storage matrix at a predetermined level of energy;
causing the hydrogen particles to impact the carbon nanotube storage matrix;
causing the hydrogen particles to be decelerated as they pass through the carbon nanotube storage matrix; and
capturing, either internally or externally, and storing the hydrogen particles by nanotubes below the surface of the carbon nanotube storage matrix.

26. The method of claim 25 wherein the kinetic energy level of the hydrogen particles upon impact with the carbon nanotube storage matrix varies between approximately 25 keV and 75 keV.

27. The method of claim 25 wherein the energy level of the hydrogen particles upon impact with the carbon nanotube storage matrix is approximately 50 keV.
